(19) United States
(12) Patent Application Publication
(10) Pub. No.: US 2001/0017502 A1
(43) Pub. Date: Aug. 30, 2001

(54) Multilayer piezoactuator and method for manufacturing same

(76) Inventors: Andreas Kappel, Brunnthal (DE); Randolf Mock, Muenchen (DE); Hans Meixner, Haar (DE)

Correspondence Address: Bell, Boyd & Lloyd LLC, P.O. Box 1135, Chicago, IL, 60690, US

(21) Appl. No.: 09/764,596

(22) Filed: Jan. 19, 2001

Related U.S. Application Data
(62) Division of application No. 09/365,208, filed on Jul. 30, 1999.

(30) Foreign Application Priority Data
Jul. 30, 1998 (DE) 19834461.9

(51) Int. Cl. H01L 41/08

(52) U.S. Cl. 310/328

(57) ABSTRACT

A piezoelectric multilayer actuator made of at least two individual piezoelectric layers which can be driven electrically by at least one electrode, wherein the actuator exhibits a hexagonal cross-sectional geometry.

### BACKGROUND OF THE INVENTION

1. Field of the Invention

The present invention relates to a multilayer actuator based on a piezoelectric operating principle, and a method manufacturing the same.

2. Description of the Prior Art

For the triggering of a rapid positioning process, a multilayer piezoactuator (PMA=piezoelectric multilayer actuator) is increasingly used. For manufacturing-related reasons, an actuator of this type, up until now, has been available only with a rectangular or square cross-sectional geometry. With respect to a miniaturization of the components, an effort is made to use the available constructive space in an optimal manner. Since the placement of a square multilayer piezoactuator in a cylindrical housing uses only 63.7% of the cross-sectional surface of the housing, the values for the electromagnetically important characteristics of such a multilayer element, such as the rigidity cₚ=(A/L) E_{M}[N/m], with A=cross-sectional surface [m²], L=actuator length [m], E_{M}=modulus of elasticity [GPa], and the blocking force F_{B}=A E_{M}d₃₃E_{F}[N], with d₃₃=piezomodulus [m/V], E_{F}=electrical field strength [V/m], reach only approximately 0.64 times those values of a cylindrical PMA that is optimal in this sense. However, from the manufacturing point of view, a cylindrical PMA can be manufactured only at great expense and, thus, not profitably. For example, the grinding of a ceramic-type piezoactuator involves a higher expense due to the requirement of a particularly expensive diamond grinding disk. “Ceramic-type material” is understood to mean either a ceramic or a material that is mechanically similar thereto.

Since the actuator geometry is determined by the respective application, there results a restriction for the cross-sectional geometry of a generally-used cylindrical housing. Accordingly, such a housing is often unnecessarily large in diameter. Up until now, no practical solution has been known for the removal or minimization of this problem.

An object of the present invention, therefore, is to provide a multilayer piezoactuator whose cross-sectional geometry is optimized in relation to a cylindrical housing, and which is, nonetheless, comparatively easy to manufacture.

### SUMMARY OF THE INVENTION

The fundamental idea of the present invention is based on the use of a multilayer piezoactuator having a hexagonal cross-sectional geometry with such configuration, there results the advantage that the filling factor of the PMA is increased by 30%, up to 82.7%, in comparison to an actuator having a square cross-sectional geometry. In addition, conventional rectilinear saw cuts can be used for the manufacturing of a hexagonal PMA. This advantageously distinguishes the hexagonal basic structure from higher-order polygons.

Since the circumference of a hexagon increases only slightly in relation to that of a square, the additional expense associated with the subsequent processing of the outer surfaces of the PMA is negligible.

Accordingly, in an embodiment of the present invention, a piezoelectric multilayer actuator of hexagonal cross-sectional geometry is provided which includes at least two individual piezoelectric layers; at least two electrodes, wherein the electrodes are alternately layered with the piezoelectric layers; and a housing of circular cross-section.

In an embodiment, at least one of the electrodes is made of AgPd.

In an embodiment, at least one of the piezoelectric layers is made of one of the group consisting of PbTiO₃, PbZrO₃, and PZT.

In an embodiment, an opening is provided on one side of each of the electrodes.

In an embodiment, the piezoelectric multilayer actuator further includes means for alternating external contacting of the electrodes, wherein a multilayer electrode structure is formed which is substantially similar to a multiple plate capacitor.

In a further embodiment of the present invention, a method for manufacturing a piezoelectric multilayer actuator of hexagonal cross-sectional geometry is provided, wherein the actuator includes at least two individual piezoelectric layers alternately layered with at least two electrodes, the method including the steps of: forming at least two green parts, each green part being provided with an electrode structure on an upper side; stacking the green parts one over the other; connecting the green parts to form a compact solid element; separationally sawing the compact solid element to obtain at least one piezoelectric multilayer element of hexagonal cross-sectional geometry; and introducing the piezoelectric multilayer element into a housing of circular cross-section.

In an embodiment, the step of connecting the green parts is performed via a sintering process.

In an embodiment, the step of forming the at least two green parts is performed via at least one of foil casting and foil drawing.

In an embodiment, each of the electrode structures is applied to its respective green part via a screen printing process.

In an embodiment, the electrodes are isolated from the compact solid element by parallel saw cuts that are rotated by 60°.

In an embodiment, each of the electrode structures is formed of a regular pattern of a plurality of hexagonal electrodes.

In an embodiment, a plurality waste regions are provided on the each of the electrode structures between the plurality of hexagonal electrodes, the waste regions being filled with a filling material having a thickness substantially equal to a thickness of the electrode structure.

In an embodiment, the method further includes the step of: applying an external contact onto planar external surfaces of the piezoelectric multilayer element.

In an embodiment, on the planar external surfaces, at least every other electrode includes an opening.

In an embodiment, the step of applying the external contact is performed via a process of laser soldering of electrical contact lugs.

Additional features and advantages of the present invention are described in, and will be apparent from, the Detailed Description of the Preferred Embodiments and the Drawing.

### DESCRIPTION OF THE DRAWINGS

FIG. 1 shows the relevant cross-sectional geometries of the multilayer piezoactuator of the present invention;

FIG. 2 shows a view of an undivided piezoelectric element;

FIG. 3a shows a perspective view of the multilayer piezoactuator of the present invention; and

FIG. 3b shows, in cross-sectional view, the multilayer piezoactuator of FIG. 3a.

### DETAILED DESCRIPTION OF THE PREFERRED EMBODIMENTS

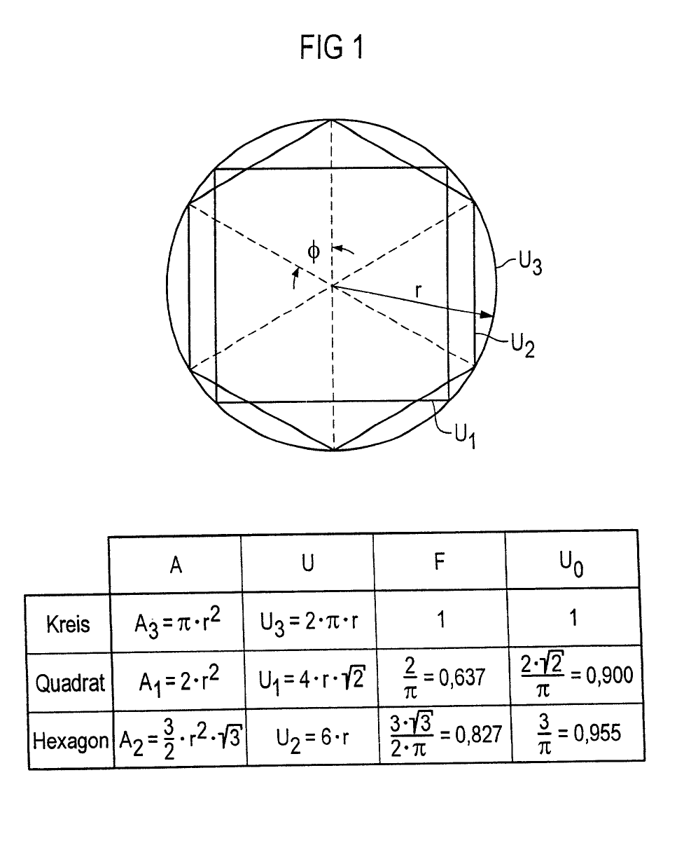

In FIG. 1, a circular circumference U₃ is shown in a top view, as well as the circumferential geometries of both a square U, and a hexagon U₂ which fill this circle. The respectively filled surfaces correspond to the cross-sectional geometry of a circle, a square or a hexagon. The angle bisectors of the hexagon are shown in broken lines. In addition, the angle, designated ω, of each of these angle bisectors with respect to one another is shown. The radius of the circle, which corresponds to half the length of the angle bisectors of the square and hexagon, is designated r.

In the following table, the relation between the filling surface A, circumference U, filling factor F in relation to the circle, and circumference U₀ in relation to the circle, is shown for a circle, a square or, respectively, a hexagon.

| | A | U | F | U₀ |
|---|---|---|---|---|
| Circle | A₃ = π · r² | U₃ = 2 · π · r | 1 | 1 |
| Square | A₁ = 2 · r² | U₁ = 4 · r · ✓2 | 2/π = 0.637 | (2 · ✓2)/π = |
| | | | | 0.900 |
| Hexagon | A₂ = | U₂ = 6 · r | (3 · ✓3)/(2 · π) | 3/π = 0.955 |
| | (3/2)r² · √3 | | =0.827 | |

In the table, the filling factor F of the hexagon, increased in relation to the square, with 82.7% of the surface of the circle again can be seen.

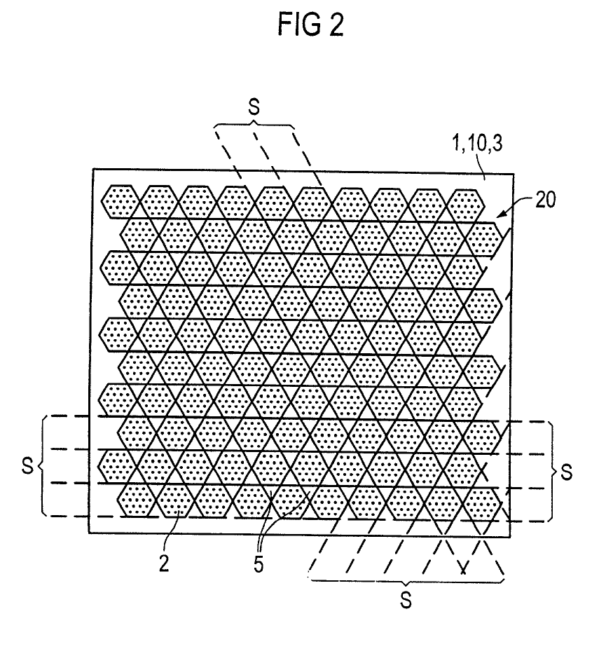

FIG. 2 shows a top view of an individual layer 1, provided with an electrode structure 20, of a PMA. This is, for example, a green part 10 i.e., a not-yet-sintered individual layer or an already-sintered layer. The electrode layer 20 consists of several hexagonal rectified electrodes 2 that touch at their comers. Between the electrodes 2, which are preferably made of AgPd, triangular waste areas 5 can be seen that, in the simplest case, are not filled with material. The electrode structure 20 advantageously is applied on the upper side of the green part 10 by means of screen printing. The green part 10 preferably is constructed as a foil, also called a green foil. The green foil is advantageously obtained by means of foil drawing or foil casting. However, a pressed structure also can be used.

For the manufacture of a compact PMA, given a ceramic-type piezoactuator material, several printed green parts 10 are stacked on one another congruently and are sintered under the action of pressure or temperature. These parts are released later, if necessary. The screen printing process for the electrodes 2 and the stacking of the green parts 10 thereby advantageously takes place in such a manner that the desired multilayer structure arises by means of a later external contacting 6. FIG. 2 thus also corresponds to the top view of a compact (e.g., already-sintered) piezoelectric solid element 3 or to an already-sintered individual layer 1.

For simplified contacting, it is advantageous for the electrode 2 to include at least one opening on at least one side. As such, green parts 10 can be stacked in such a way that the opening of electrodes 2 positioned one over the other is attached in alternating fashion at an opposite side of the hexagon. This measure brings about the result that, after an isolation at two opposite sides of a multilayer piezoactuator, only every second electrode extends onto the surface. In this way, the respectively desired group of electrodes 2 can be addressed by means of a simple electrical contacting; e.g., a planar contacting.

For the isolation of a multilayer piezoactuator, the compact solid element 3 is divided by several rectilinear saw cuts S. A particular advantage of a hexagonal cross-sectional geometry is that, due to the rectilinear saw cuts S, the separational sawing previously used for the isolation of the PMA can be used unchanged. For example, the solid element 3 is clamped in oriented fashion on a carrier that allows, on the one hand, defined angular rotations of 60°, and allows, on the other hand, a translational displacement of the cutting table. The saw cuts S required for the isolation can be produced in this way. The remaining waste takes up a quarter of the substrate surface. In order to achieve a homogeneous construction of the stacked green parts 10, and in order to reduce the inner mechanical deformation occurring in the sintering process, the triangular waste regions 5 are preferably filled with a filling material corresponding to the thickness of the electrode structure 20; e.g., by screen printing of this waste region 5 with isolated islands of the electrode material.

An external contacting 6 of the electrodes 2, which are oriented in alternating fashion, is applied on the PMA, preferably by means of laser soldering, or the like, of electrical contact lugs on the planar outer surfaces of the constructive part. In this way, an advantageous multilayer electrode structure resembling a multiple plate capacitor can be manufactured; e.g., of a group of electrodes 2 with openings arranged in alternating fashion on opposite sides of the PMA.

An advantage of a multilayer piezoactuator with a hexagonal cross-sectional geometry is further explained on the basis of the following sample calculation:

If E_{M}=38 [GPa] is assumed for the modulus of elasticity of a ceramic, and d₃₃=650* 10⁻¹²[m/V] is assumed for the piezomodulus, the following results for a PMA with a square cross-sectional geometry with the dimension (width*depth*length) 7*7*30 mm that is placed in a cylindrical housing with an inner diameter of 10 mm:

Rigidity Cₚ=62 [N/μm], blocking force F_{B}=2421 [N] with E_{F}=2 kV/mm]

Under the same housing conditions, the following results for a hexagonal PMA with an edge length of the hexagon corresponding to a half inner diameter of the housing of 5 mm:

Rigidity Cₚ=82 [N/μm], blocking force F_{B}=3209 [N] with E_{F}=2[kV/mm]

The basic hexagonal structure is distinguished in relation to higher-order polygons in that, with these polygons, a parqueting of the surface cannot be realized, under the secondary condition that the individual parts can be isolated later by separation sawing. Since the circumference of a hexagon increases only by 6% in relation to that of a square, the additional expense for the subsequent processing of the outer surfaces of the PMA is negligible. Perovskites (including BaTiO₃, SrTiO₃, PbTiO₃, KaTiO₃, PbZrO₃, Pb(Zr₁₋ₓTix)0₃ (PZT), KNbO₃, LiNbO₃, LiTaO₃) are preferably used as piezoelectric materials. Any suitable metal, or a metal alloy, can be used as the electrode material, through noble metals are preferred. AgPd is particularly preferred.

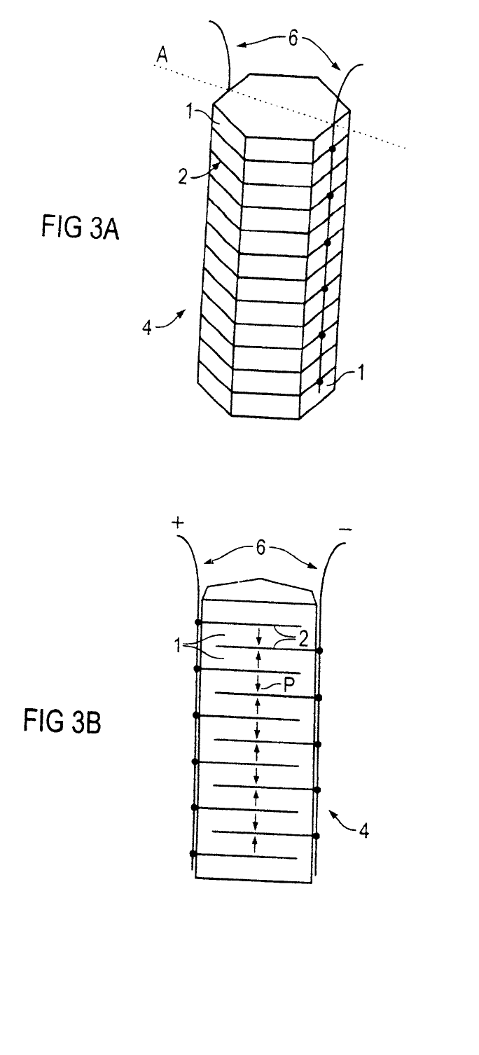

FIG. 3a shows an oblique view of a hexagonal PMA that is constructed from alternately-applied piezoelectric individual layers I and electrodes 2. The external contacting 6 is constructed in such a way that every second electrode 2 is respectively contacted on an external contacting 6. The dotted line A designates the conceived curve of a separating line for the representation of a sectional image according to FIG. 3b.

In FIG. 3b, the PMA of FIG. 3a is shown as a sectional representation along the dividing line A. The alternating contacting of the electrodes 2 in relation to the external contacting 6 can be seen. This is achieved by means of an opening at the electrodes 2 through which the cut runs. Via the application of an electrical voltage to the external contacting 6, this electrode structure behaves in the manner of a multilayer capacitor. The electrical field that occurs during the application is identified by the respective arrows.

Due to the considerably better (in comparison to a square basic surface) approximation of the optimal circular shape, there also results the further functional advantages that, for example, the introduction of force into the element to be driven takes place more homogeneously, the mechanical stress distribution in the multilayer element is more uniform, and the field strength non-homogeneity at the comers of the electrode structure 20 is reduced due to the more blunt edge angle (120° instead of 90°).

Although the present invention has been described with reference to specific embodiments, those of skill in the art will recognize that changes may be made thereto without departing from the spirit and scope of the invention as set forth in the hereafter appended claims.

We claim as our invention:

1. A piezoelectric multilayer actuator of hexagonal cross-sectional geometry, comprising:
at least two individual piezoelectric layers;
at least two electrodes, wherein the electrodes are alternately layered with the piezoelectric layers; and
a housing of circular cross-section.

2. A piezoelectric multilayer actuator as claimed in claim 1, wherein at least one of the electrodes is made of AgPd.

3. A piezoelectric multilayer actuator as claimed in claim 1, wherein at least one of the piezoelectric layers is made of one of the group consisting of PbTiO₃, PbZrO₃, and PZT.

4. A piezoelectric multilayer actuator as claimed in claim 1, wherein an opening is provided on one side of each of the electrodes.

5. A piezoelectric multilayer actuator as claimed in claim 1, further comprising:
means for alternating external contacting of the electrodes, wherein a multilayer electrode structure is formed which is substantially similar to a multiple plate capacitor.

6. A method for manufacturing a piezoelectric multilayer actuator of hexagonal cross-sectional geometry, wherein the actuator includes at least two individual piezoelectric layers alternately layered with at least two electrodes, the method comprising the steps of:
forming at least two green parts, each green part being provided with an electrode structure on an upper side;
stacking the green parts one over the other;
connecting the green parts to form a compact solid element;
separationally sawing the compact solid element to obtain at least one piezoelectric multilayer element of hexagonal cross-sectional geometry; and
introducing the piezoelectric multilayer element into a housing of circular cross-section.

7. A method for manufacturing a piezoelectric multilayer actuator as claimed in claim 6, wherein the step of connecting the green parts is performed via a sintering process.

8. A method for manufacturing a piezoelectric multilayer actuator as claimed in claim 6, wherein the step of forming the at least two green parts is performed via at least one of foil casting and foil drawing.

9. A method for manufacturing a piezoelectric multilayer actuator as claimed in claim 6, wherein each of the electrode structures is applied to its respective green part via a screen printing process.

10. A method for manufacturing a piezoelectric multilayer actuator as claimed in claim 6, wherein the electrodes are isolated from the compact solid element by parallel saw cuts that are rotated by 60°.

11. A method for manufacturing a piezoelectric multilayer actuator as claimed in claim 6, wherein each of the electrode structures is formed of a regular pattern of a plurality of hexagonal electrodes.

12. A method for manufacturing a piezoelectric multilayer actuator as claimed in claim 11, wherein a plurality waste regions are provided on the each of the electrode structures between the plurality of hexagonal electrodes, the waste regions being filled with a filling material having a thickness substantially equal to a thickness of the electrode structure.

13. A method for manufacturing a piezoelectric multilayer actuator as claimed in claim 6, further comprising the step of:
applying an external contact onto planar external surfaces of the piezoelectric multilayer element.

14. A method for manufacturing a piezoelectric multilayer actuator as claimed in claim 13, wherein, on the planar external surfaces, at least every other electrode includes an opening.

15. A method for manufacturing a piezoelectric multilayer actuator as claimed in claim 13, wherein the step of applying the external contact is performed via a process of laser soldering of electrical contact lugs.
